(19) United States
(12) Patent Application Publication
(10) Pub. No.: US 2025/0122611 A1
(43) Pub. Date: Apr. 17, 2025

(54) METHOD FOR PROCESSING SUBSTRATE

(71) Applicant: TES Co., Ltd, Yongin-si (KR)

(72) Inventors: Sungwoo LEE, Yongin-si (KR); Sang Hak Yeo, Yongin-si (KR); Kwanwoo Lee, Yongin-si (KR); Suk hwan Kim, Yongin-si (KR)

(73) Assignee: TES Co., Ltd, Yongin-si (KR)

(21) Appl. No.: 18/915,404

(22) Filed: Oct. 15, 2024

(30) Foreign Application Priority Data
Oct. 13, 2023 (KR) 10-2023-0137158

(51) Int. Cl. C23C 16/04; C23C 16/26; H01J 37/32; H01L 21/02; H01L 21/3065

(52) U.S. Cl. CPC C23C 16/045; C23C 16/26; H01J 37/32082; H01L 21/02115; H01L 21/02274; H01L 21/3065; H01J 2237/3321; H01J 2237/334

(57) ABSTRACT

Disclosed is a substrate processing method including a gap-fill process capable of preventing pattern damage. The substrate processing method includes a deposition step of depositing an amorphous carbon layer on a substrate having pattern walls formed thereon, wherein a gap is defined between the pattern walls; an etching step of removing an overhang formed at a top of the pattern wall using an etching gas; and a repeating step of repeating the deposition step and the etching step so as to fill the gap with the amorphous carbon layer, wherein the etching gas used in the etching step contains carbon dioxide.

### CROSS-REFERENCE TO RELATED APPLICATION

This application claims priority from Korean Patent Application No. 10-2023-0137158 filed on Oct. 13, 2023 in the Korean Intellectual Property Office, and all the benefits accruing therefrom under 35 U.S.C. 119, the contents of which in its entirety are herein incorporated by reference.

### BACKGROUND

The present disclosure relates to a substrate processing method for manufacturing a semiconductor device. More specifically, the present disclosure relates to a substrate processing method including an amorphous carbon gap-fill process of a semiconductor device using carbon dioxide.

As a semiconductor device becomes smaller and more highly integrated, increasingly finer patterns are required.

In a manufacturing process of the semiconductor device, formation of a pattern is usually implemented through a photolithography process. For example, an amorphous carbon layer (ACL) is deposited as a hard mask on a layer to be patterned, and a photoresist film is formed thereon, and then exposure, development, etching, ashing, and strip processes are performed thereon to form a desired pattern.

The amorphous carbon layer is generally deposited using a PECVD (Plasma Enhanced Chemical Vapor Deposition) process as a plasma processing process.

In this regard, the amorphous carbon layer used as a hard mask needs to be filled into a gap within an already formed pattern, and this process is called a gap-fill process. The gap-fill process is also generally performed using the PECVD process.

However, the carbon radicals in the plasma have no directionality. Thus, when performing the gap-fill process using the PECVD process, the ions accumulate like snow without directionality in depositing the amorphous carbon on a micro pattern.

As a result, during the formation of the amorphous carbon layer, a larger amount of amorphous carbon is deposited on a top of the gap pattern than elsewhere, resulting in an overhang that reduces a distance between pattern walls. Due to the overhang, a top opening of the gap pattern formed on the substrate may become narrow or even blocked, thereby preventing the gap from being entirely filled, such that a void may occur.

To prevent this situation, a cyclic gap-fill method that repeats the deposition and etching of the amorphous carbon has been proposed. The overhang that occurs on the top of the pattern during the deposition of amorphous carbon is removed by etching, and the deposition and etching are repeatedly performed such that the gap is filled with amorphous carbon.

In the cyclic gap-fill process, oxygen gas (O₂) or hydrogen gas (H₂) is mainly used as etching gas for the amorphous carbon layer. However, although oxygen and hydrogen gas are effective in etching the amorphous carbon layer in the plasma etching process, the pattern exposed to the etching may be damaged by ion bombardment. This damage to the pattern widens a predetermined CD (Critical Dimension), making it difficult to achieve a fine pattern.

### SUMMARY

A purpose of the present disclosure is to provide a substrate processing method including a gap-fill process that may effectively reduce a size of the void in an amorphous carbon gap-fill process while preventing damage to the pattern wall.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a method for processing a substrate, the method comprising: a deposition step of depositing an amorphous carbon layer on a substrate having pattern walls formed thereon, wherein a gap is defined between the pattern walls; an etching step of removing an overhang formed at a top of the pattern wall using an etching gas; and a repeating step of repeating the deposition step and the etching step so as to fill the gap with the amorphous carbon layer, wherein the etching gas used in the etching step contains carbon dioxide.

In accordance with some embodiments of the method of the first aspect, each of the deposition step and the etching step is performed in a state where RF (radio frequency) power is applied to a plasma processing apparatus.

In accordance with some embodiments of the method of the first aspect, in the etching step, etching of the amorphous carbon layer and producing of a carbon compound are achieved simultaneously.

In accordance with some embodiments of the method of the first aspect, in the etching step, a non-volatile carbon compound layer is produced.

In accordance with some embodiments of the method of the first aspect, the etching step is performed under a condition of a carbon dioxide flow rate of about 500 to 1000 sccm, a substrate temperature of about 500 to 600° C., an RF power of about 500 to 1500 W, and an internal pressure of the plasma processing apparatus of about 1 to 7 Torr.

In accordance with some embodiments of the method of the first aspect, in the etching step, a hydrocarbon is additionally supplied into the plasma processing apparatus.

In accordance with some embodiments of the method of the first aspect, the method further comprises, after filling the gap with the amorphous carbon layer, an exposing step of exposing a portion of the pattern wall. The exposing step may be performed by a CMP (Chemical Mechanical Polishing) process or a recess process.

A second aspect of the present disclosure provides a method for processing a substrate, the method comprising: a placing step of placing a substrate into a plasma processing apparatus, wherein the substrate has pattern walls formed thereon, wherein a gap is defined between the pattern walls; a deposition step of depositing an amorphous carbon layer on the substrate having the pattern walls by a PECVD process; an etching step of removing an overhang formed at a top of the pattern wall by a plasma etching process; and a repeating step of repeating the deposition step and the etching step so as to fill the gap with the amorphous carbon layer, wherein in the etching step, the amorphous carbon layer is etched and, at the same time, a pattern wall protective layer is formed on the pattern wall.

In accordance with some embodiments of the method of the second aspect, in the etching step, an etching gas containing carbon dioxide is supplied into a plasma processing apparatus.

In accordance with some embodiments of the method of the second aspect, the etching step is performed under a condition of a carbon dioxide flow rate of about 500 to 1000 sccm, a substrate temperature of about 500 to 600° C., an RF power of about 500 to 1500 W, and an internal pressure of the plasma processing apparatus of about 1 to 7 Torr.

In accordance with some embodiments of the method of the second aspect, the pattern wall protection layer includes a non-volatile carbon compound layer.

In accordance with some embodiments of the method of the second aspect, in the etching step, hydrocarbon is additionally supplied into the plasma processing apparatus.

In accordance with some embodiments of the method of the second aspect, the method further comprises, after filling the gap with the amorphous carbon layer, an exposing step of exposing a portion of the pattern wall. The exposing step may be performed by a CMP process or a recess process.

Using the carbon dioxide as the etching gas for the amorphous carbon layer according to the present disclosure, the pattern wall protection layer may be produced while the amorphous carbon layer is etched during the etching of the amorphous carbon layer. Thus, the size of the void may be effectively reduced in the amorphous carbon gap-fill process while preventing damage to the pattern wall.

Effects of the present disclosure are not limited to the effects mentioned above, and other effects not mentioned will be clearly understood by those skilled in the art from the descriptions below.

### BRIEF DESCRIPTION OF THE DRAWINGS

FIG. 1 is a flow chart schematically showing a substrate processing method according to an embodiment of the present disclosure.

FIG. 2 is a cross-sectional view schematically showing intermediate structures corresponding to intermediate steps of the substrate processing method of FIG. 1.

FIG. 3 is a schematic cross-sectional view of an example of a plasma processing apparatus that may be used in the method of the present disclosure.

FIG. 4 shows whether there is a change in a pattern when oxygen gas is used as an etching gas and shows whether there is a change in a pattern when carbon dioxide gas is used as an etching gas.

FIG. 5 is a photograph showing a result of a gap-fill process of each of Comparative Example 1 and Present Example 1.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the embodiments of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The following is a detailed description of a substrate processing method according to a preferred embodiment of the present disclosure with reference to the attached drawings.

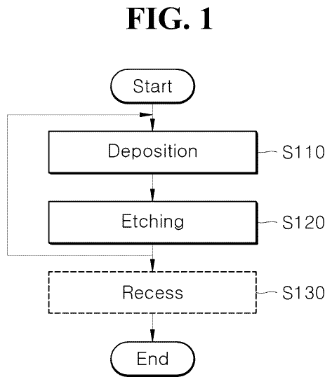

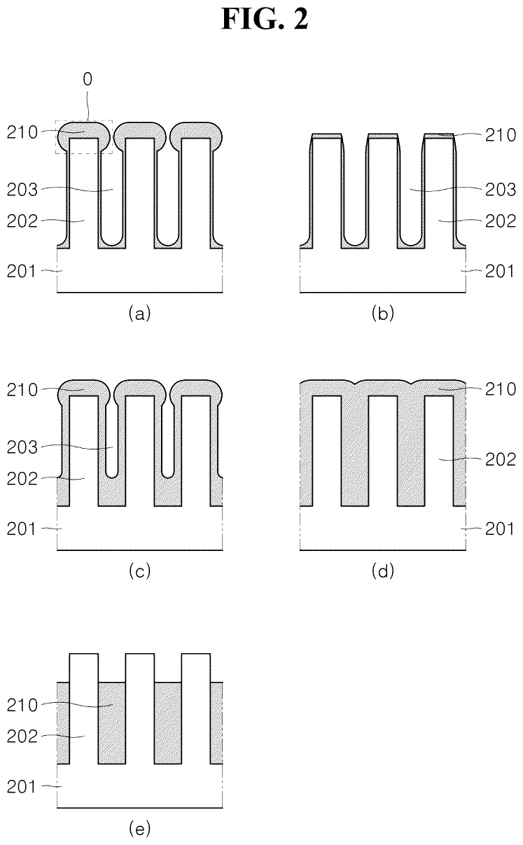

FIG. 1 is a flow chart schematically showing a substrate processing method according to an embodiment of the present disclosure. FIG. 2 is a cross-sectional view schematically showing intermediate structures corresponding to intermediate steps of the substrate processing method of FIG. 1. Reference to FIG. 2 will be made in describing the substrate processing method according to FIG. 1.

Referring to FIG. 1, the substrate processing method according to the present disclosure includes a deposition step S110 and an etching step S120. The deposition step S110 and the etching step S120 are repeatedly performed in multiple cycles.

The substrate to be processed is a substrate 201 having a gap 203 formed between a pattern wall 202 and an adjacent pattern wall 202 thereto, that is, between adjacent pattern walls. The pattern walls 202 may be formed from a stack of alternately laminated silicon oxides and silicon nitrides, also called an ONO stack. The substrate processing method according to the present disclosure includes a gap-fill process for filling the gap 203 between the pattern walls 202 adjacent to each other with amorphous carbon. The gap-fill process is generally intended to prevent collapse of the pattern walls.

The deposition step S110 and the etching step S120 are performed by supplying a reaction gas such as a deposition gas and an etching gas into a plasma processing apparatus while the substrate is received in the plasma processing apparatus.

In the deposition step S110, an amorphous carbon layer is deposited using a hydrocarbon. The deposition step S110 and the etching step S120 may be performed in the plasma processing apparatus under a plasma environment, that is, under a state where RF power is applied thereto. In this case, the deposition is PECVD deposition, and the etching is plasma etching.

The deposition step S110 may use hydrocarbons such as C₂H₂, C₃H₆, trimethylbenzene, etc. to form an amorphous carbon layer. In one example, the oxygen gas (O₂) may be added to the reaction gas supplied during amorphous carbon deposition. When the oxygen gas is added thereto, the stress of the formed amorphous carbon layer may be relieved, and a denser amorphous carbon layer may be deposited.

The gap-fill process requires the deposition step S110. However, as described above, in this case, as shown in (a) of FIG. 2, a larger amount of amorphous carbon is deposited on the top of the pattern wall 202 than elsewhere, such that the overhang O occurs such that the distance between the pattern walls adjacent to each other is reduced, thereby narrowing the top opening of the gap pattern formed on the substrate or even entirely blocking the top opening. As a result, the gap cannot be entirely filled with amorphous carbon, and a large void may be formed.

In accordance with the present disclosure to solve this problem, a deposition-etching cyclic method is used in which the deposition step S110 and the etching step S120 are repeatedly performed, thereby increasing the filling percentage of the amorphous carbon and reducing the void. Although not shown in FIG. 1 for simplicity, a final step of the deposition-etching cyclic method is the deposition step. In one example, the deposition steps of the deposition-etching cyclic method may be performed at the same deposition rate, or may be performed so that the deposition rate gradually increases as the order of the deposition steps increases. When the deposition rate gradually increases, the throughput may be improved.

In the etching step S120, the overhang O formed on the top of the pattern wall 202 is removed as shown in (b) of FIG. 2 via etching using an etching gas. As a result, the amorphous carbon layer 210 of the uniform thickness may remain on an entirety of a side surface and an upper surface of the pattern wall 202.

Afterwards, the deposition step S110 is performed again to increase the thickness of the amorphous carbon layer 210 deposited between the pattern walls 202 adjacent to each other as shown in (c) of FIG. 2.

Afterwards, the etching step S120 is performed again to remove the overhang. As a result, the amorphous carbon layer 210 of the uniform thickness larger than the thickness of the amorphous carbon layer 210 in (b) of FIG. 2 may be formed.

After this cyclic deposition-etching process has been completed, the gap 203 between the pattern walls 202 adjacent to each other is filled with the amorphous carbon layer 210 via the final deposition step, as shown in (d) of FIG. 2.

The oxygen gas or hydrogen gas was mainly used as the etching gas for the amorphous carbon layer. However, although the oxygen gas and the hydrogen gas are efficient in etching the amorphous carbon layer, they may cause damage to the pattern by removing the amorphous carbon of the wall and the bottom of the pattern. Therefore, it is necessary to achieve both removal of the amorphous carbon and protection of the pattern.

In accordance with the present disclosure, the amorphous carbon layer may be etched and at the same time a pattern wall protection layer may be created under etching gas control.

More specifically, in accordance with the present disclosure, the etching step S120 was performed using the etching gas containing carbon dioxide.

In the etching step S120, a carbon dioxide flow rate may be in a range of about 500 to 1000 sccm, a substrate temperature may be in a range of about 500 to 600° C., the RF power may be in a range of about 500 to 1500 W, and an internal pressure of the plasma processing apparatus may be in a range of about 1 to 7 Torr for process uniformity and etching of upper/lower portions of the pattern in a limited manner thereto. The above-defined conditions about the carbon dioxide flow rate, the substrate temperature, the RF power, and the internal pressure of the plasma processing apparatus may provide a balance between the etch rate of the amorphous carbon layer and the deposition rate of the pattern wall protection layer. In one embodiment, the etching step may be performed under the conditions of the carbon dioxide flow rate of about 700 sccm, the substrate temperature of about 550° C., the RF power of about 1 kW, and the internal pressure of about 4 Torr of the plasma processing apparatus.

When the carbon dioxide is used, carbon radicals, oxygen radicals, and carbon monoxide radicals are simultaneously produced under plasma discharge. In this regard, a significant portion of the oxygen radicals produce volatile byproducts via reaction with the amorphous carbon layer, thereby contributing to the etching of the amorphous carbon layer. On the other hand, the carbon monoxide radicals and the carbon radicals react with amorphous carbon to produce some volatile products. In this regard, the non-volatile carbon compounds, for example, non-volatile carbon compounds containing ethers, aldehydes, and carboxyl groups may be produced. A layer of this non-volatile carbon compound may act as a protective film for the pattern against plasma ions.

Conventionally, the oxygen and hydrogen plasmas only etch the amorphous carbon layer. However, in accordance with the present disclosure, the carbon dioxide plasma simultaneously performs etching and deposition on the carbon layer. Conventionally, the CD is unintentionally widened due to the damage to the pattern under the attack of the plasma ions. However, according to the present disclosure, the non-volatile carbon compound layer formed in the carbon dioxide plasma process acts as the protective film against the plasma ions, thereby suppressing the damage to the pattern.

Furthermore, hydrocarbons together with carbon dioxide may be supplied into the plasma reaction apparatus. In this case, the deposition rate or the etching rate may be stably controlled depending on a content ratio of carbon dioxide and hydrocarbons.

In one example, after the gap-fill process of filling the gap 203 with the amorphous carbon layer 210 has been completed, an exposing step S130 of exposing a portion of the pattern wall may be additionally performed, as shown in (e) of FIG. 2. In the exposing step S130, a top portion of the pattern wall may be exposed. In the exposing step S130, the top portion of the pattern wall may protrude from the amorphous carbon layer 210. The reason for exposing the top portion of the pattern wall after the gap-fill process is to additionally form an upper pattern wall that matches the underlying pattern wall by deposition. If the top portion of the pattern wall is not exposed, it is difficult to form an upper pattern wall to match the underlying pattern wall. The exposing step S130 is performed by a CMP process or a recess process.

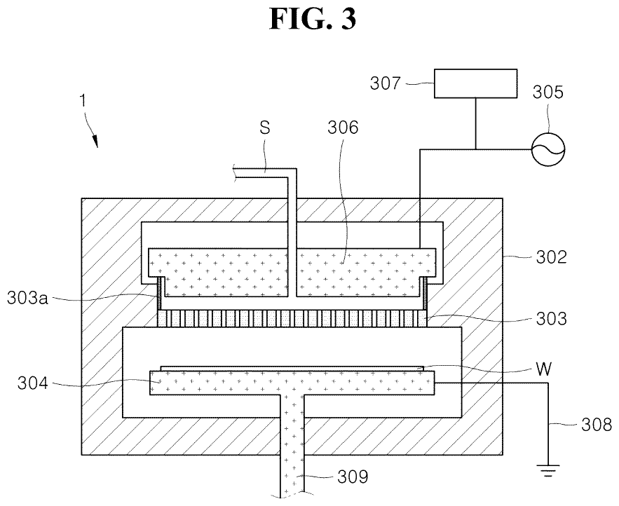

FIG. 3 is a cross-sectional view schematically showing an example of a plasma processing apparatus that may be used in the method of the present disclosure.

Referring to FIG. 3, the illustrated substrate processing apparatus 1 comprises a reaction chamber 302, a showerhead 303, a susceptor 304, an RF power source 305, and a first electrode 306.

The showerhead 303 is disposed at an upper portion of an inner space of the reaction chamber 302 and sprays gas injected through a single or multiple gas supply lines S connected to an external gas supply device (not shown) into the inner space of the chamber 302.

In this embodiment, the gas supply line S may include a hydrocarbon supply line for supplying hydrocarbon for deposition and a carbon dioxide supply line for supplying the carbon dioxide for etching. The hydrocarbon together with an inert gas such as argon gas or helium gas as a carrier gas may be supplied into the inner space of the reaction chamber. Furthermore, the carbon dioxide and the hydrocarbon may be supplied together into the inner space of the chamber 302 during etching.

The first electrode 306 is electrically connected to the RF power source 305 and is used as an electrode for inducing plasma discharge within the chamber 302. In the example as illustrated in FIG. 3, the showerhead 303 is electrically connected 303a to the first electrode 306, so that a combination of the first electrode 306 and the showerhead 303 functions as a single electrode. Accordingly, the RF power generated from the RF power source 305 is applied to the inner space of the reaction chamber 302 through the first electrode 306 and the showerhead 303. A RF filter 307 serves to remove signal interference occurring around the reaction chamber 302.

The susceptor 304 is disposed at a lower portion of the inner space of the reaction chamber 302. The substrate W is loaded and supported onto the susceptor 304. The susceptor 304 may have a vertically movable shaft 309. The susceptor 304 may be equipped with a temperature control means for heating/cooling the substrate. Furthermore, the susceptor 304 may function as a ground electrode, as shown in the example in FIG. 3. A separate ground line 308 may be equipped to further improve grounding performance. Although not shown, the susceptor 304 itself may be connected to a high-frequency power source or a DC power source and thus may act as a second electrode (bias electrode).

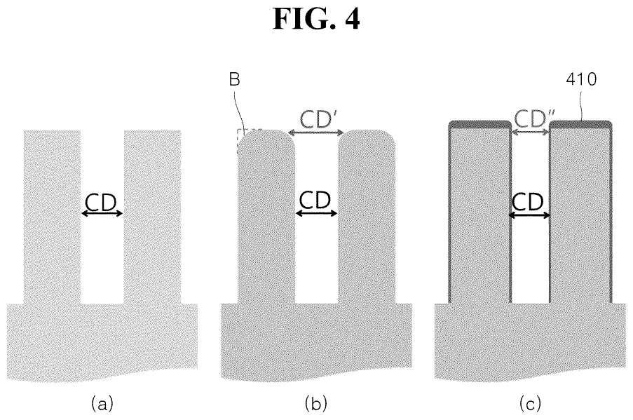

FIG. 4 shows whether there is a change in a pattern when oxygen gas is used as an etching gas and shows whether there is a change in a pattern when carbon dioxide gas is used as an etching gas.

In FIG. 4, (a) shows a state in which a pattern is formed on a substrate, (b) shows a state in which the pattern is damaged by plasma ions, and (c) shows a state in which a protective film 410 is formed on the pattern such that the pattern is not damaged.

When the pattern is damaged by plasma ions, as shown in a portion B of FIG. 4, the CD may increase to CD′. Thus, a fine line width may not be realized. However, when the protective film 410 is formed on the pattern such that the pattern is not damaged by plasma ions, the CD″ after the plasma process may be equal to the CD before the plasma process.

As described above, this protective film 410 may be made of the non-volatile carbon compound including ether, aldehyde, carboxyl group, etc. as produced through the plasma etching using carbon dioxide as an etching gas.

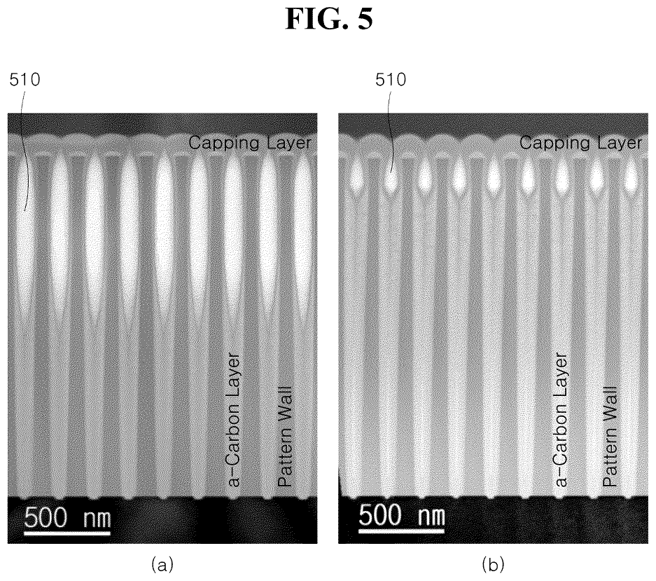

FIG. 5 is a photograph showing a result of the gap-fill process of each of Comparative Example 1 and Present Example 1.

In FIG. 5, (a) shows the gap-fill process result when an amorphous carbon layer is deposited using a single PECVD deposition process (Comparative Example 1). In FIG. 5, (b) shows the gap-fill process result when PECVD deposition-carbon dioxide plasma etching—PECVD deposition—carbon dioxide plasma etching-PECVD deposition are sequentially performed (Present Example 1).

In (a) in FIG. 5, it may be identified that a void 510 is formed at a quite large size. In contrast thereto, in (b) of FIG. 5, it may be identified that the void 510 is significantly small. That is, it may be identified that the deposition-etching cyclic gap-fill process may contribute to the reduction of the size of the void. This reduction of the size of the void contributes to the improvement of the stability of the amorphous carbon layer formed by the gap-fill process.

Furthermore, using carbon dioxide as an etching gas for the amorphous carbon layer according to the present disclosure, the amorphous carbon layer may be etched, and, at the same time, the pattern wall protection layer may be formed, during the etching of the amorphous carbon layer. Thus, the void size may be effectively reduced in the amorphous carbon gap-fill process, while preventing damage to the pattern wall, thereby preventing an increase of the CD, etc.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A method for processing a substrate, the method comprising:
a deposition step of depositing an amorphous carbon layer on a substrate having pattern walls formed thereon, wherein a gap is defined between the pattern walls;
an etching step of removing an overhang formed at a top of the pattern wall using an etching gas; and
a repeating step of repeating the deposition step and the etching step so as to fill the gap with the amorphous carbon layer,
wherein the etching gas used in the etching step contains carbon dioxide.

2. The method of claim 1, wherein each of the deposition step and the etching step is performed in a state where RF (radio frequency) power is applied to a plasma processing apparatus.

3. The method of claim 2, wherein in the etching step, etching of the amorphous carbon layer and producing of a carbon compound are achieved simultaneously.

4. The method of claim 2, wherein in the etching step, a non-volatile carbon compound layer is produced.

5. The method of claim 2, wherein the etching step is performed under a condition of a carbon dioxide flow rate of about 500 to 1000 sccm, a substrate temperature of about 500 to 600° C., an RF power of about 500 to 1500 W, and an internal pressure of the plasma processing apparatus of about 1 to 7 Torr.

6. The method of claim 2, wherein in the etching step, a hydrocarbon is additionally supplied into the plasma processing apparatus.

7. The method of claim 1, wherein the method further comprises, after filling the gap with the amorphous carbon layer, an exposing step of exposing a portion of the pattern wall.

8. The method of claim 7, the exposing step is performed by a CMP process or a recess process.

9. A method for processing a substrate, the method comprising:
a placing step of placing a substrate into a plasma processing apparatus, wherein the substrate has pattern walls formed thereon, wherein a gap is defined between the pattern walls;
a deposition step of depositing an amorphous carbon layer on the substrate having the pattern walls by a PECVD process;
an etching step of removing an overhang formed at a top of the pattern wall by a plasma etching process; and
a repeating step of repeating the deposition step and the etching step so as to fill the gap with the amorphous carbon layer,
wherein in the etching step, the amorphous carbon layer is etched and, at the same time, a pattern wall protective layer is formed on the pattern wall.

10. The method of claim 9, wherein in the etching step, an etching gas containing carbon dioxide is supplied into a plasma processing apparatus.

11. The method of claim 9, wherein the etching step is performed under a condition of a carbon dioxide flow rate of about 500 to 1000 sccm, a substrate temperature of about 500 to 600° C., an RF power of about 500 to 1500 W, and an internal pressure of the plasma processing apparatus of about 1 to 7 Torr.

12. The method of claim 9, wherein the pattern wall protection layer includes a non-volatile carbon compound layer.

13. The method of claim 10, wherein in the etching step, hydrocarbon is additionally supplied into the plasma processing apparatus.

14. The method of claim 9, wherein the method further comprises, after filling the gap with the amorphous carbon layer, an exposing step of exposing a portion of the pattern wall.

15. The method of claim 14, the exposing step is performed by a CMP process or a recess process.
